(19) United States
(12) Patent Application Publication
(10) Pub. No.: US 2022/0271061 A1
(43) Pub. Date: Aug. 25, 2022

(54) MANUFACTURING METHOD OF PIXEL STRUCTURE OF REFLECTIVE DISPLAY

(71) Applicant: GIANTPLUS TECHNOLOGY CO., LTD., Miauli County (TW)

(72) Inventors: I-Ta JIANG, Miauli County (TW); Che-Yao WU, Miauli County (TW); Kai-Ju CHOU, Miauli County (TW)

(73) Assignee: GIANTPLUS TECHNOLOGY CO., LTD., Miauli County (TW)

(21) Appl. No.: 17/743,475

(22) Filed: May 13, 2022

Related U.S. Application Data
(62) Division of application No. 17/083,317, filed on Oct. 29, 2020.

(30) Foreign Application Priority Data
Sep. 30, 2020 (TW) 109213003

(51) Int. Cl. H01L 27/12

(52) U.S. Cl. CPC H01L 27/1218; H01L 27/1288; H01L 27/1262; H01L 27/124

(57) ABSTRACT

The present disclosure discloses a manufacturing method of a pixel structure of a reflective display comprising: providing a substrate; forming a shielding layer on the substrate; forming a low reflective layer on the shielding layer; and forming a reflective layer on the low reflective layer, wherein the reflective layer comprises a plurality of reflection regions, the plurality of reflection regions are arranged at intervals, and a part of the low reflective layer is exposed between the plurality of reflection regions. In the present disclosure, the reflection of light in the gap between the pixels is avoided by the low reflective layer, such that the notice of liquid crystal disturbance by human eyes is reduced, and a reflective display with good display function and low power consumption is implemented.

### CROSS REFERENCE TO RELATED APPLICATION

This application is a Divisional of Application No. 17/083,317, filed Oct. 29, 2020, which claims the priority benefit of Taiwan Patent Application Number 109213003, filed on Sep. 30, 2020, the full disclosure of which is incorporated herein by reference.

### BACKGROUND

### Technical Field

The present disclosure relates to the technical field of a display, particularly to a manufacturing method of a pixel structure of a reflective display.

### Related Art

Electronic products are widely used in daily life with the advancement of science and technology; therefore, the reliance on electronic products for people increases. In order to use electronic products anytime and anywhere, these electronic products are developed toward the trend of being lighter, thinner, shorter, and smaller, so that users can carry these electronic products with them.

For thin and light portable electronic products, in addition to having a good display function, the display that provides the message also needs to reduce power consumption as much as possible to extend the use time. Therefore, a 30 Hz or 1 Hz refresh frequency lower than 60 Hz is used in the display panel to drive the pixel transistors, so that the purpose of reducing power consumption is achieved. However, such the driving method may cause some characteristic defects of the display panel to be noticed by human eyes. For example, when a light is reflected in a gap between a pixel and a pixel, a liquid crystal is disturbed by electric power lines on both sides to produce scan patterns or brush patterns. Since the perception ability of the human eyes is affected by the refresh rate, in a case of a high refresh rate, the scan patterns or brush patterns are not easily observed by the human eyes. However, in a case of a low refresh rate, the scan patterns or brush patterns become obvious and are observed by the human eyes.

At present, a general solution is to set a black matrix to avoid the reflection of light in the gap between pixels that disturbs the liquid crystal. However, for a reflective display panel, the black matrix also greatly reduces the reflectivity of the entire panel, resulting in decreasing the brightness of the display.

### SUMMARY

The embodiments of the present disclosure disclose a pixel structure of a reflective display and a manufacturing method thereof, in order to solve the problems of decreasing brightness caused by using a black matrix in a pixel structure of a reflective display.

The present disclosure discloses a manufacturing method of a pixel structure of a reflective display comprising: providing a substrate; forming a shielding layer on the substrate; forming a low reflective layer on the shielding layer; and forming a reflective layer on the low reflective layer, wherein the reflective layer comprises a plurality of reflection regions, the plurality of reflection regions are arranged at intervals, and a part of the low reflective layer is exposed between the plurality of reflection regions.

In the embodiments of the present disclosure, electrical disturbances from data lines or gate lines are shielded by the shielding layer in the pixel structure of the reflective display, and the brightness of the reflected light among the pixels is reduced by the low reflective layer disposed on the shielding layer. Therefore, the human eye's perception of liquid crystal disturbances is reduced. A reflective display having good display function and low power consumption is implemented.

It should be understood, however, that this summary may not contain all aspects and embodiments of the present disclosure, that this summary is not meant to be limiting or restrictive in any manner, and that the disclosure as disclosed herein will be understood by one of ordinary skill in the art to encompass obvious improvements and modifications thereto.

### BRIEF DESCRIPTION OF THE DRAWINGS

The features of the exemplary embodiments believed to be novel and the elements and/or the steps characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

FIG. 1 is a schematic diagram of a pixel structure of a reflective display of one embodiment of the present disclosure;

FIG. 2 is a graph of reflectance and thickness of the low reflective layer of one embodiment of the present disclosure;

FIG. 3 to FIG. 7 are schematic diagrams of the manufacturing process of the pixel structure of the reflective display of one embodiment of the present disclosure; and

FIG. 8 is a flow chart of the manufacturing process of the pixel structure of the reflective display of one embodiment of the present disclosure.

### DETAILED DESCRIPTION OF THE EMBODIMENTS

The present disclosure will now be described more fully hereinafter with reference to the accompanying drawings, in which exemplary embodiments of the disclosure are shown. This present disclosure may, however, be embodied in many different forms and should not be construed as limited to the embodiments set forth herein. Rather, these embodiments are provided so that this present disclosure will be thorough and complete, and will fully convey the scope of the present disclosure to those skilled in the art.

Certain terms are used throughout the description and following claims to refer to particular components. As one skilled in the art will appreciate, manufacturers may refer to a component by different names. This document does not intend to distinguish between components that differ in name but function. In the following description and the claims, the terms “include/including” and “comprise/comprising” are used in an open-ended fashion, and thus should be interpreted as “including but not limited to”. “Substantial/substantially” means, within an acceptable error range, the person skilled in the art may solve the technical problem in a certain error range to achieve the basic technical effect.

The following description is of the best-contemplated mode of carrying out the disclosure. This description is made for the purpose of illustration of the general principles of the disclosure and should not be taken in a limiting sense. The scope of the disclosure is best determined by reference to the appended claims.

Moreover, the terms “include”, “contain”, and any variation thereof are intended to cover a non-exclusive inclusion. Therefore, a process, method, object, or device that includes a series of elements not only includes these elements, but also includes other elements not specified expressly, or may include inherent elements of the process, method, object, or device. If no more limitations are made, an element limited by “include a/an . . . ” does not exclude other same elements existing in the process, the method, the article, or the device which includes the element.

In the following embodiment, the same reference numerals are used to refer to the same or similar elements throughout the disclosure.

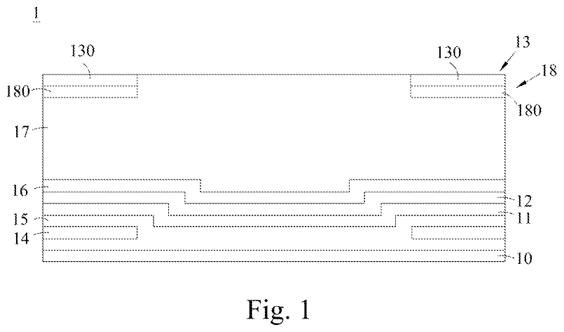

Refer to FIG. 1, which is a schematic diagram of a pixel structure of a reflective display according to one embodiment of the present disclosure. As shown in the figure, the pixel structure 1 comprises a substrate 10, a shielding layer 11, a low reflective layer 12, and a reflective layer 13. The shielding layer 11 is disposed on the substrate 10. The low reflective layer 12 is disposed on the shielding layer 11. The reflective layer 13 is disposed on the low reflective layer 12. More specifically, the reflective layer 13 comprises a plurality of reflective regions 130, and the plurality of reflective regions 130 are arranged at intervals. In other words, there are gaps between the plurality of reflective regions 130, and a part of the low reflective layer 12 is exposed from the gaps between the plurality of reflective regions 130. Therefore, the gaps between the plurality of reflective areas 130 are shielded by the low-reflective layer 12. When a lights enters the pixel structure 1 from one of the gaps, the reflection of the light is reduced by the exposed low-reflective layer 12. Thereby, the human eye's perception of liquid crystal disturbances is reduced. The various elements mentioned above will be explained below.

The substrate 10 may comprise a flexible light-transmitting material. For example, the substrate 10 may comprise a polymer, such as acryl-based resin, methacryl-based resin, polyisoprene, epoxy-based resin, urethane-based resin, siloxane-based resin, polyimide-based resin, polyamide-based, and/or any combination thereof, but the present disclosure is not limited thereto. In other embodiments, the substrate 10 may comprise a light-transmitting material having rigidity. For example, the substrate 10 may be a glass substrate or a quartz substrate.

The shielding layer 11 is disposed on the substrate 10 and used to reduce electrical interference from data lines or gate lines. In some embodiments, the shielding layer 11 may comprise pure metal, metal alloy, metal nitride, metal oxide, metal oxynitride, and/or a combination thereof, but the present disclosure is not limited thereto. For example, the shielding layer 11 may comprise metals or alloys of molybdenum, thallium, and niobium. In addition, in some embodiments, the thickness of the shielding layer 11 may be between 2,000 Å and 4,000 Å, and its thickness decision depends on the signal strength or frequency in the data line or the gate line. Specifically, the reflective layer 13 in the pixel structure 1 is affected by the signal in the datas line or the gate lines, and the extent of the influence is related to the intensity of the signal and the frequency of signal change. Therefore, when the signal intensity and frequency of signal change are high, the shielding layer 11 may be disposed of a thicker thickness, such as 4,000 Å, to avoid poor electrical properties of the reflective layer 13. Conversely, when the signal intensity and frequency of signal change are low, the shielding layer 11 may be disposed of thinner thickness, such as 2,000 Å, to reduce the overall thickness of the pixel structure 1.

The low reflective layer 12 is disposed on the shielding layer 11 and is used to reduce the brightness of the reflected light. The low reflective layer 12 may not transmit light or partially transmit light. In some embodiments, the low reflective layer 12 may comprise molybdenum oxide. The molybdenum oxide is formed on the shielding layer 11 by physical vapor deposition. Furthermore, in the manufacturing process thereof, the low reflective layer 12 and the shielding layer 11 may use the same mask to reduce the complexity of the manufacturing process. Therefore, the shielding layer 11 and the low reflective layer 12 made of the same mask may completely overlap. The detailed manufacturing process will be discussed further below.

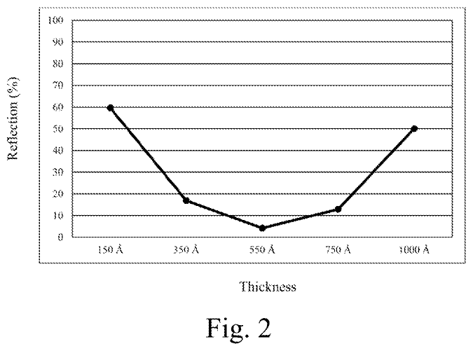

Refer to FIG. 2, which is a graph of reflectance and thickness of the low reflective layer according to one embodiment of the present disclosure. As shown in the figure, the reflectance of the low reflective layer 12 under visible light is related to the thickness, and the reflectance is minima at a specific thickness, and the lowest value of the reflectance is 2%. In some embodiments, the relationship between reflectance and thickness of the low reflective layer is shown in table 1. When the thickness of the low reflective layer 12 is between 150 Å and 1000 Å, the low reflective layer 12 has a reflectance of about 4% to 60%. Preferably, when the thickness of the low reflective layer 12 is between 500 Å and 800 Å, the thickness of the low reflective layer 12 has a reflectance of about 4% to 15%. More preferably, when the thickness of the low reflective layer 12 is 550 Å, the low reflective layer 12 has the lowest reflectance of 4%.

TABLE 1

| thickness (Å) | reflectance (%) |
|---|---|
| 150 | 59.7 |
| 350 | 16.9 |
| 550 | 4.2 |
| 750 | 12.9 |
| 1000 | 50.08 |

The reflective layer 13 is disposed on the low reflective layer 12 and is used to reflect light from the external environment. For example, the reflective layer 13 may comprise one or more films with high reflection, and the films may be composed of metal or metal nitride. Alternatively, the films may be composed of epoxy resin and formed on the reflective layer 13 by coating. More specifically, the thickness of the reflective layer 13 may be between 1,000 Å to 3,000 Å.

Refer to FIG. 1 again. As shown in the figure, in some embodiments, the pixel structure 1 may further comprise a data line 14. The data line 14 is disposed on the substrate 10 and between the substrate 10 and the shielding layer 11. The data line 14 may comprise pure metal, metal alloys, metal nitrides, metal oxides, metal oxynitrides, and/or combinations thereof, but the present disclosure is not limited thereto. More specifically, the thickness of the data line 14 may be between 2,000 Å to 4,000 Å.

In some embodiments, the pixel structure 1 may also comprise a gate line. The gate line is disposed on the substrate 10 and between the substrate 10 and the shielding layer 11. The gate line and the data line 14 may be formed by the same patterned conductive layer. However, the present disclosure is not limited thereto. In other embodiments, the gate line may also be provided on a different layer from the data line 14. The gate line may comprise pure metal, metal alloy, metal nitride, metal oxide, metal oxynitride, and/or a combination thereof, but the present disclosure is not limited thereto. More specifically, the thickness of the gate line may be between 2,000 Å to 4,000 Å.

In some embodiments, the pixel structure 1 may also comprise thin-film transistors. The thin-film transistors are disposed on the substrate 10 and used to control the pixels. Specifically, each of the thin film transistors may comprise a gate, a drain, a source, a channel layer, and an insulating layer, respectively. The gates may be electrically connected to the gate line. The gates may be formed by the same patterned conductive layer, such as a metal layer or an alloy layer. Specifically, the gates may comprise aluminum, platinum, silver, titanium, molybdenum, zinc, tin, and/or a combination thereof, but the present disclosure is not limited thereto. The drains and the sources may be formed by the same patterned conductive layer, and they may comprise the same or different materials as the gates. The channel layers may be formed of the same layer of patterned semiconductor, and each of the channel layers may be a single layer or have a multilayer structure. The channel layers may comprise silicon (for example, amorphous silicon, polycrystalline silicon, single crystalline silicon), oxide semiconductor (for example, indium oxide, gallium oxide, zinc oxide, indium gallium oxide, indium zinc oxide, indium tin oxide, or indium gallium zinc oxide), organic semiconductors, or other semiconductor materials. Each of the insulating layers may be a single-layer or a multi-layer, and the insulating layer may comprise inorganic materials (for example, silicon nitride, silicon oxide, silicon oxynitride), organic materials (for example, polyimide, polyester, polymethylmethacrylate, polyvinylphenol, polyvinyl alcohol, polytetrafluoroethylene), but the present disclosure is not limited thereto.

In some embodiments, the pixel structure 1 may further comprise a first protective layer 15. The first protective layer 15 is disposed on the substrate 10, and the first protective layer 15 may comprise silicon nitride, aluminum oxide, titanium oxide, silicon oxide, silicon nitride, silicon oxynitride, zirconium oxide, hafnium oxide, and/or any combination thereof, or other materials recognized by a person of ordinary skill in the art. More specifically, the thickness of the first protective layer 15 may be between 2,000 Å to 6,000 Å.

In some embodiments, the pixel structure 1 may further comprise a second protective layer 16. The second protection layer 16 is disposed on the low reflective layer 12. The second protective layer 16 may comprise the same or similar material as the material used to the first protective layer 15, so the description thereof may be omitted. In addition, the thickness of the second protective layer 16 may be between 2,000 Å to 6,000 Å.

In some embodiments, the pixel structure 1 may further comprise an organic layer 17. The organic layer 17 is disposed on the second protective layer 16. The organic layer 17 may comprise polyimide-based resin, epoxy-based resin, acrylic-based resin, or other materials recognized by a person of ordinary skill in the art. More specifically, the thickness of the organic layer 17 may be between 10,000 Å to 40,000 Å.

In some embodiments, the pixel structure 1 may further comprise a transparent conductive layer 18. The transparent conductive layer 18 is disposed on the organic layer 17. The transparent conductive layer 18 comprises a plurality of conductive regions 180, and the plurality of conductive regions 180 are arranged at intervals. That is, there are gaps between the plurality of conductive regions 180, and a part of the low reflective layer 12 is exposed from the gaps between a plurality of conductive regions 180. When a light enters the pixel structure 1 through the gaps between the plurality of conductive regions 180, the light is absorbed by the low reflective layer 12. Therefore, the moving of the reflective light at the pixel structure 1 causing the disturbance of liquid crystal observed by human eyes is avoided. In some embodiments, the transparent conductive layer 18 may comprise indium tin oxide. Alternatively, the transparent conductive layer 18 may comprise indium zinc oxide. More specifically, the thickness of the transparent conductive layer 18 may be between 500 Å to 2,000 Å.

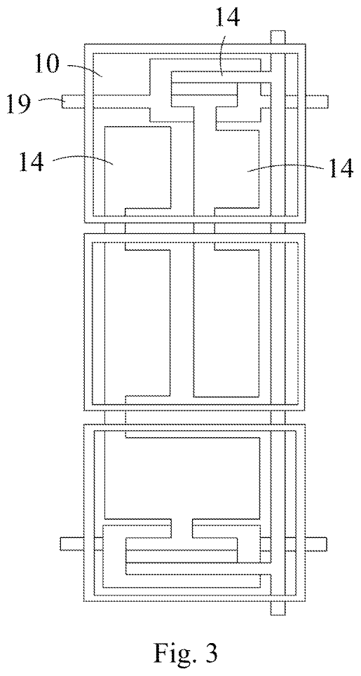

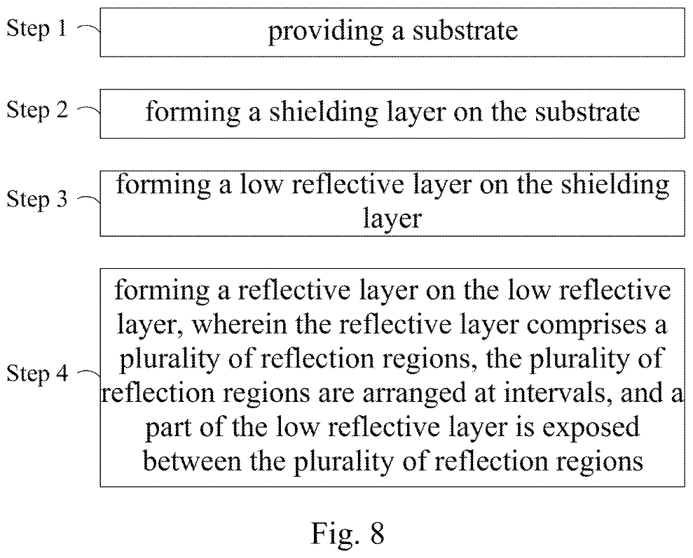

Refer to FIG. 3 to FIG. 8, which are schematic diagrams and a flow chart of the manufacturing process of the pixel structure of the reflective display of one embodiment of the present disclosure. It should be noted that only the steps using a mask are exemplarily described hereinafter, to facilitate understanding of the present disclosure. Therefore, the actual manufacturing process may comprise other steps not described, so the present disclosure should not be limited.

As shown in FIG. 3, a first patterned conductive layer is formed to the substrate 10 by a first mask after providing a substrate 10. The first patterned conductive layer may comprise a gate line 19. Then, a second patterned conductive layer is formed to the substrate 10 by a second mask. The second patterned conductive layer may comprise a data line 14.

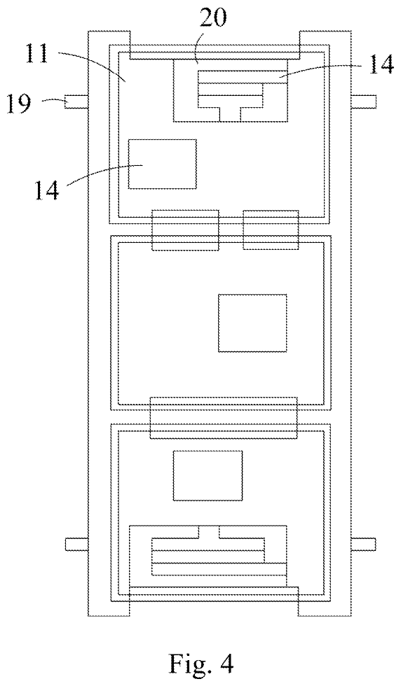

As shown in FIG. 4, a shielding layer 11 is formed to the substrate 10 by a third mask. The shielding layer 11 covers at least a part of the data line 14 and the gate line 19. So that the interference of the data line 14 and the gate line 19 to the reflective layer 13 forming after is reduced. In some embodiments, the shielding layer 11 may not cover thin-film transistors, but only cover at least a part of the data line 14 and the gate line 19 to avoid the excessive capacitance generating by the shielding layer 11 and the thin-film transistors.

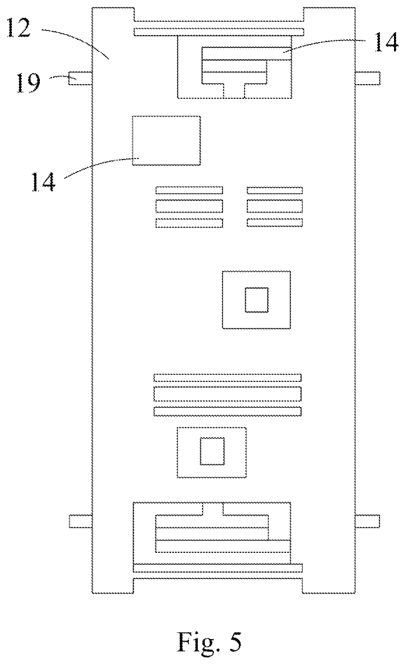

As shown in FIG. 5, a low reflective layer 12 is formed to the shielding layer 11 by a third mask. The low reflective layer 12 and the shielding layer 11 both use the third mask. Because a mask corresponding to the reflective layer 12 is not required, the manufacturing cost of the pixel structure 1 may be reduced. In addition, the reflective layer 12 formed by the third mask and the shielding layer 11 formed by the third mask completely overlap. In the present embodiment, molybdenum oxide of a molybdenum oxide target is deposited to the shielding layer 11 by physical vapor deposition to form the low reflective layer 12. The reflectance of the low reflective layer 12 is controlled by the thickness of the molybdenum oxide.

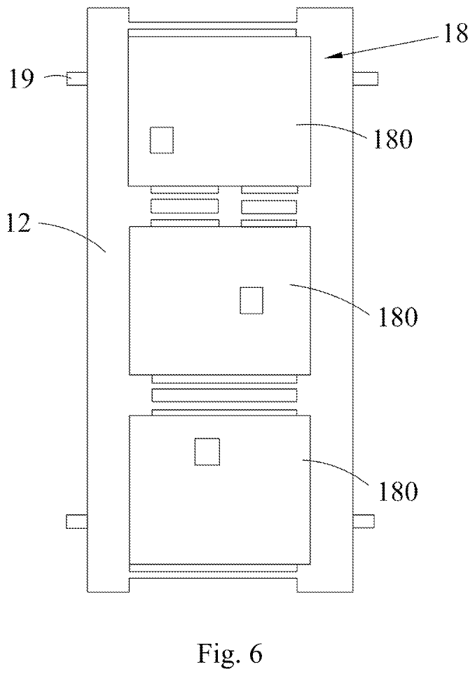

As shown in FIG. 6, after sequentially forming a second protective layer 16 and an organic layer 17 to the low reflective layer 12, a transparent conductive layer 18 is formed to the organic layer 17 by a fourth mask. The transparent conductive layer 18 comprises a plurality of conductive regions 180. The plurality of conductive areas 180 are arranged at intervals. A part of the low reflective layer 12 is exposed from the plurality of conductive areas 180.

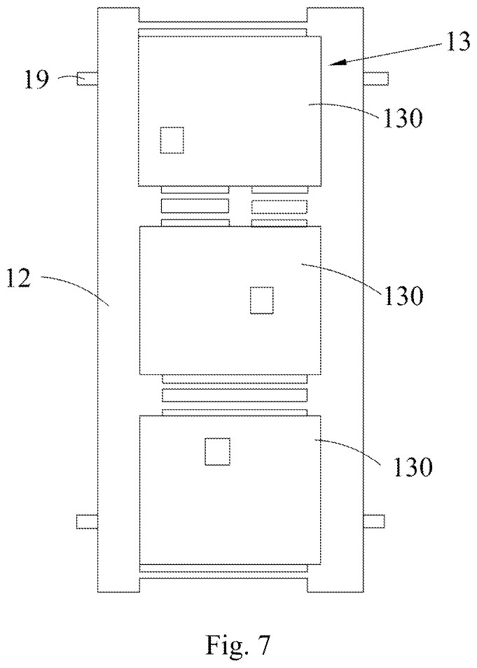

As shown in FIG. 7, a reflective layer 13 is formed to the transparent conductive layer 18 by a fifth mask. The reflective layer 13 comprises a plurality of reflective regions 130, and the plurality of reflective regions 130 are arranged at intervals. A part of the low reflective layer 12 is exposed from the plurality of reflective regions 130. Therefore, when a light enters the pixel structure 1 from the position of the non-reflective area, the reflection of the light may be avoided by the low reflective layer 12. Thereby, the disturbance of the liquid crystal is reduced.

In summary, in the embodiments of the present disclosure, electrically disturbances from data lines or gate lines are shielded by the shielding layer in the pixel structure of the reflective display, and the brightness of the reflected light among the pixels is reduced by the low reflective layer disposing on the shielding layer. Therefore, the human eye's perception of liquid crystal disturbances is reduced. A reflective display having good display function and low power consumption is implemented.

It is to be understood that the term “comprises”, “comprising”, or any other variants thereof is intended to encompass a non-exclusive inclusion, such that a process, method, article, or device of a series of elements not only comprise those elements but also comprises other elements that are not explicitly listed, or elements that are inherent to such a process, method, article, or device. An element defined by the phrase “comprising a . . . ” does not exclude the presence of the same element in the process, method, article, or device that comprises the element.

Although the present disclosure has been explained in relation to its preferred embodiment, it does not intend to limit the present disclosure. It will be apparent to those skilled in the art having regard to this present disclosure that other modifications of the exemplary embodiments beyond those embodiments specifically described here may be made without departing from the spirit of the disclosure. Accordingly, such modifications are considered within the scope of the disclosure as limited solely by the appended claims.

What is claimed is:

1. A manufacturing method of a pixel structure of a reflective display, comprising:
providing a substrate;
forming a shielding layer on the substrate;
forming a low reflective layer on the shielding layer; and
forming a reflective layer on the low reflective layer, wherein the reflective layer comprises a plurality of reflection regions, the plurality of reflection regions are arranged at intervals, and a part of the low reflective layer is exposed between the plurality of reflection regions.

2. The manufacturing method of a pixel structure of a reflective display according to claim 1, wherein the shielding layer and the low reflective layer are formed by the same mask.

3. The manufacturing method of a pixel structure of a reflective display according to claim 1, wherein the low reflective layer is formed by a physical vapor deposition method.

4. The manufacturing method of a pixel structure of a reflective display according to claim 3, wherein the target material used in the physical vapor deposition method comprises molybdenum oxide.

5. The manufacturing method of a pixel structure of a reflective display according to claim 1, wherein a thickness of the low reflective layer is between 150 Å and 1000 Å.

6. The manufacturing method of a pixel structure of a reflective display according to claim 5, wherein the thickness of the low reflective layer is between 500 Å and 800 Å.

7. The manufacturing method of a pixel structure of a reflective display according to claim 5, wherein a reflectivity of the low-reflective layer is between 2% and 60% under visible light.

8. The manufacturing method of a pixel structure of a reflective display according to claim 1, wherein the low-reflective layer is opaque.

9. The manufacturing method of a pixel structure of a reflective display according to claim 1, wherein a thickness of the shielding layer is between 2,000 Å to 4,000 Å.

10. The manufacturing method of a pixel structure of a reflective display according to claim 1, wherein the shielding layer is formed by metal.
